(19) United States
(12) Patent Application Publication
(10) Pub. No.: US 2012/0001552 A1
(43) Pub. Date: Jan. 5, 2012

(54) Failure Detection System and Method for LED Lighting Equipment

(75) Inventors: Kun-Cheng Tsai, Taipei City (TW); Yung-Chuan Wen, Taipei City (TW)

(73) Assignee: INSTITUTE FOR INFORMATION INDUSTRY, Taipei (TW)

(21) Appl. No.: 12/904,550

(22) Filed: Oct. 14, 2010

(30) Foreign Application Priority Data
Jul. 5, 2010 (TW) 99122013

(51) Int. Cl. H05B 37/03; G06F 19/00; G01R 31/00

(52) U.S. Cl. 315/129; 702/58

(57) ABSTRACT

The present disclosure provides an LED lighting equipment failure detecting system for detecting if an LED lighting equipment is failure. The LED lighting equipment failure detecting system includes a current measuring unit, a parameter measuring unit, a storage unit and a control unit. The current measuring unit and the parameter measuring unit measure a present current value and a present operating parameter of at least one LED of the LED lighting equipment respectively. The control unit calculates a present condition parameter of the LED according to the present current value and the present operating parameter. The control unit calculates a condition parameter difference between the present condition parameter and the initial condition parameter stored in the storage unit. If the condition parameter difference is more than the abnormal condition threshold, the control unit determines that the LED of the LED lighting equipment is abnormal.

### RELATED APPLICATIONS

This application claims priority to Taiwan Application Serial Number 99122013, filed Jul. 5, 2010, which is herein incorporated by reference.

### BACKGROUND

1. Technical Field

The present invention relates to a failure detecting system, method and a computer-readable storage medium for storing thereof. More particularly, the present invention relates to an LED lighting equipment failure detecting system, method and a computer-readable storage medium for storing thereof.

2. Description of Related Art

A light-emitting diode (LED) is a semiconductor light source. LEDs are used as indicator lamps in many devices, and are increasingly used for lighting. Early LEDs emitted low-intensity red light, but modern versions are available across the visible, ultraviolet and infrared wavelengths, with very high brightness.

Volt-ampere characteristic of LED is distributed. Therefore, not only volt-ampere characteristic of different LEDs differs, but also volt-ampere characteristic of LEDs with the same serial model differs. Accordingly, electrical specifications of LED lighting equipments are different. In addition, there are several abnormal conditions for LED lighting equipment, such as overheat, abnormal intensity control, open circuit, short circuit, decreased emitting capability. It would be complicated to solve different abnormal conditions with different solutions.

There are lots of lighting systems (such as road lighting systems) constructed. Electrical information of lighting system can be collected by manpower for failure detection, which requires many people. Besides, additional failure detection devices can be installed on each lighting system, which costs a lot.

### SUMMARY

An LED lighting equipment failure detecting system is provided in this disclosure. The LED lighting equipment failure detecting system is used for detecting if an LED lighting equipment is failure, wherein the LED lighting equipment includes at least one LED. The LED lighting equipment failure detecting system determines if the LED lighting equipment is failure according to the relation between the present current value and the present operating parameter of the LED of the LED lighting equipment. The LED lighting equipment failure detecting system includes a current measuring unit, a parameter measuring unit, a storage unit and a control unit. The control unit builds connections with the current measuring unit and the parameter measuring unit, and is electrically connected with the storage unit. The current measuring unit measures a present current value of the LED. The parameter measuring unit measures a present operating parameter of the LED. Wherein, the parameter measuring unit may be a temperature measuring unit, an intensity measuring unit, a voltage measuring unit or a luminance measuring unit. An initial condition parameter of the LED is stored in the storage unit. The control unit includes a receiving module, a condition parameter calculating module, a difference calculating module and a condition determining module. The receiving module receives the present current value from the current measuring unit, and receives the present operating parameter from the parameter measuring unit. The condition parameter calculating module calculates a present condition parameter of the LED of the LED lighting equipment according to the present current value and the present operating parameter. The difference calculating module calculates a condition parameter difference between the present condition parameter and the initial condition parameter. The condition determining module determines if the condition parameter difference is more than an abnormal condition threshold. If the condition parameter difference is more than the abnormal condition threshold, the LED of the LED lighting equipment is determined abnormal.

According to one embodiment of this disclosure, the condition parameter calculating module may include a relation parameter calculator and a condition parameter converter. The relation parameter calculator calculates at least one relation parameter between the present current value and the present operating parameter. The condition parameter converter converts the at least one relation parameter into the present condition parameter.

According to another embodiment of this disclosure, the control unit may build connections with the current measuring unit and the parameter measuring unit through electrical connection.

According to another embodiment of this disclosure, the LED lighting equipment failure detecting system may further include a data transmission interface. The control unit may build connections with the current measuring unit and the parameter measuring unit through the data transmission interface.

According to another embodiment of this disclosure, the LED lighting equipment failure detecting system may further include a notice signal generating unit, which is electrically connected with the control unit. If the LED of the LED lighting equipment is determined abnormal, the notice signal generating unit may generate a notice signal.

According to another embodiment of this disclosure, when the LED lighting equipment failure detecting system is set to an initial stage, the condition parameter calculating module takes the present condition parameter as the initial condition parameter, and the condition parameter calculating module stores the initial condition parameter into the storage unit.

Besides, an LED lighting equipment failure detecting method is provided in this disclosure. The LED lighting equipment failure detecting method is used for detecting if an LED lighting equipment is failure, wherein the LED lighting equipment includes at least one LED. In the LED lighting equipment failure detecting method, if the LED lighting equipment is failure is determined according to the relation between the present current value and the present operating parameter of the LED of the LED lighting equipment. The LED lighting equipment failure detecting method may take the form of a computer program product stored on a computer-readable storage medium having computer-readable instructions embodied in the medium. The LED lighting equipment failure detecting method includes the following steps: a present current value and a present operating parameter of the LED are measured. The present operating parameter of the LED of the LED lighting equipment may be temperature, intensity, voltage or luminance of the LED of the LED lighting equipment. A present condition parameter of the LED of the LED lighting equipment is calculated according to the present current value and the present operating parameter. An initial condition parameter of the LED of the LED lighting equipment is obtained from a storage unit. A condition parameter difference between the present condition parameter and the initial condition parameter is calculated. Determine if the condition parameter difference is more than an abnormal condition threshold. If the condition parameter difference is more than the abnormal condition threshold, the LED of the LED lighting equipment is determined abnormal.

According to one embodiment of this disclosure, the step of calculating the present condition parameter of the LED of the LED lighting equipment according to the present current value and the present operating parameter may include the following steps: at least one relation parameter between the present current value and the present operating parameter is calculated. The at least one relation parameter is converted into the present condition parameter.

According to another embodiment of this disclosure, the LED lighting equipment failure detecting method may further include: if the LED of the LED lighting equipment is determined abnormal, a notice signal may be generated.

According to another embodiment of this disclosure, the LED lighting equipment failure detecting method may further include: the present condition parameter may be stored into the storage unit as the initial condition parameter during an initial stage.

Above all, if the LED of the LED lighting equipment is abnormal can be determined according to the current value and operating parameter of the LED of the LED lighting equipment. In addition, if an initial stage is set, the initial condition parameter can be obtained for latter abnormality determination. Therefore, even if different LEDs or LED lighting equipments are applied, abnormality thereof can be determined after setting to the initial stage. Besides, different types of abnormality, such as overheat, open circuit, short circuit, decreased LED emitting capability, abnormal intensity control or any other abnormality, can be determined. In addition, several LED lighting equipments can share a single control, which save cost.

These and other features, aspects, and advantages of the present invention will become better understood with reference to the following description and appended claims. It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiments, with reference made to the accompanying drawings as follows:

FIG. 1 illustrates a block diagram of an LED lighting equipment failure detecting system according to one embodiment of this invention; and

FIG. 2 is a flow diagram of an LED lighting equipment failure detecting method according to another embodiment of this invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

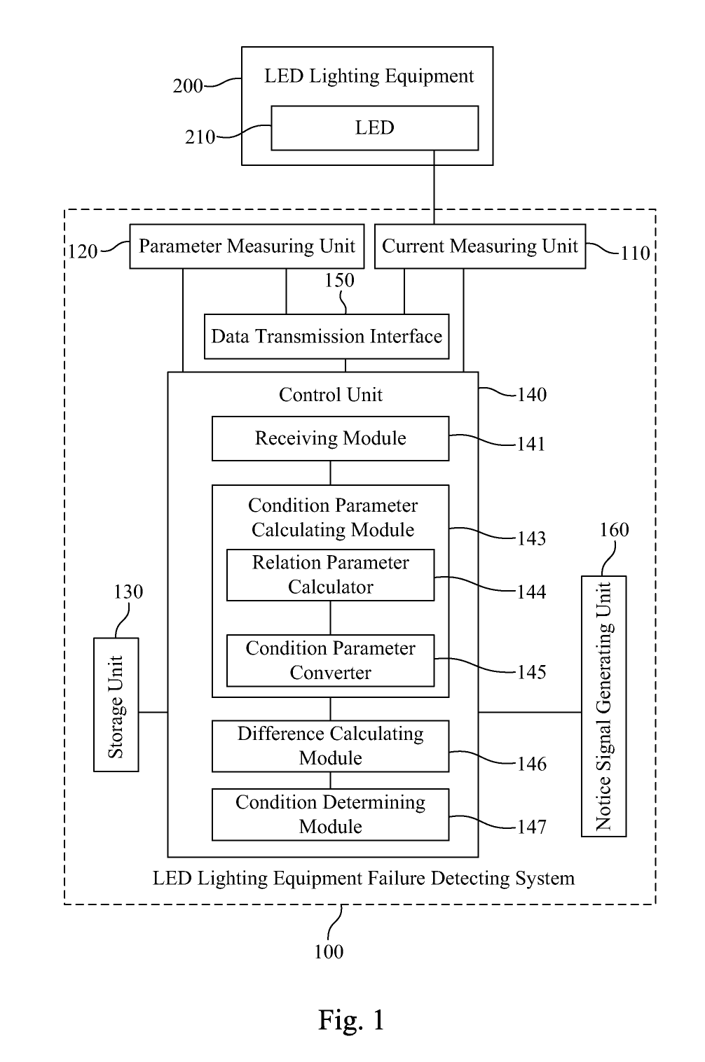

FIG. 1 illustrates a block diagram of an LED lighting equipment failure detecting system according to one embodiment of this invention. The LED lighting equipment failure detecting system 100 is used for detecting if an LED lighting equipment 200 is failure, wherein the LED lighting equipment 200 includes at least one LED 210. The relation between the present current value and the present operating parameter of the LED 210 can be utilized to determine if the LED 210 of the LED lighting equipment 200 is failure. The present operating parameter of the LED 210 may be temperature, intensity, voltage, luminance or any other operating parameter of the LED 210. Therefore, the relations between the present current value and different types of present operating parameters of the LED 210 can be utilized to determine different types of abnormality of the LED 210 of the LED lighting equipment 200. For example, relation between the present current value and the present temperature of the LED 210 can be utilized to determine if the LED 210 is overheated; relation between the present current value and the present intensity of the LED 210 can be utilized to determine if the intensity control of the LED 210 is abnormal; relation between the present current value and the present voltage of the LED 210 can be utilized to determine if a short circuit or an open circuit occurs in the LED 210; relation between the present current value and the present luminance of the LED 210 can be utilized to determine if the LED 210 has decreased light emitting capabilities. Therefore, the LED lighting equipment failure detecting system 100 determines if the LED lighting equipment 200 is failure according to the relation between the present current value and the present operating parameter of the LED 210 of the LED lighting equipment 200.

The LED lighting equipment failure detecting system 100 includes a current measuring unit 110, a parameter measuring unit 120, a storage unit 130 and a control unit 140. The control unit 140 builds connections with the current measuring unit 110 and the parameter measuring unit 120, and is electrically connected with the storage unit 130. The control unit 140 may be an Integrated Circuit (IC), a processing unit or any other type of the control unit. The storage unit 130 may be a Read Only Memory (ROM), a Flash Memory, a Floppy Disk, a Hard Disk Drive (HDD), an Optical Disk Drive (ODD), USB Flash Disk, a tape or any other storage unit.

The current measuring unit 110 measures a present current value of the LED 210. The parameter measuring unit 120 measures a present operating parameter of the LED 210. Wherein, the parameter measuring unit may be a temperature measuring unit, an intensity measuring unit, a voltage measuring unit, a luminance measuring unit or any other type of the parameter measuring unit. Therefore, the present operating parameter of the LED 210 measured by the parameter measuring unit 120 may be the present temperature, the present intensity, the present voltage, the present luminance or any other present operating parameter of the LED 210 of the LED lighting equipment 200. An initial condition parameter of the LED 210 is stored in the storage unit 130.

The control unit 140 includes a receiving module 141, a condition parameter calculating module 143, a difference calculating module 146 and a condition determining module 147. The receiving module 141 receives the present current value from the current measuring unit 110, and receives the present operating parameter from the parameter measuring unit 120. Wherein, the control unit 140 builds connections with the current measuring unit 110 and the parameter measuring unit 120 through electrical connection, such that the receiving module 141 of the control unit 140 can receive the present current value and the present operating parameter from the current measuring unit 110 and the parameter measuring unit 120 respectively. Besides, the LED lighting equipment failure detecting system 100 may further include a data transmission interface 150. The control unit 140 builds connections with the current measuring unit 110 and the parameter measuring unit 120 through the data transmission interface 150. Therefore, the receiving module 141 of the control unit 140 can receive the present current value and the present operating parameter from the current measuring unit 110 and the parameter measuring unit 120 respectively through the data transmission interface 150. The data transmission interface 150 may be a wired network, a wireless network or any other wired or wireless data transmission interface. If the data transmission interface 150 is a wireless network, the control unit 140 can be installed regardless of the position of the LED lighting equipment 200. In other words, the control unit 140 is not necessary to be installed near the LED lighting equipment 200, which eliminates space limitation or wiring limitation for installing the LED lighting equipment failure detecting system 100. Besides, since wiring limitation is eliminated, single control unit 140 can detect failure of several LED lighting equipments, which saves costs.

The condition parameter calculating module 143 calculates a present condition parameter of the LED 210 of the LED lighting equipment 200 according to the present current value and the present operating parameter. The difference calculating module 146 calculates a condition parameter difference between the present condition parameter and the initial condition parameter. The difference calculating module 146 may utilize subtraction, the method to calculate Pearson product-moment correlation coefficient, or any other method to calculate any other type of difference. In addition, when the LED lighting equipment failure detecting system 100 is set to an initial stage, the condition parameter calculating module 143 may take the present condition parameter as the initial condition parameter, and the condition parameter calculating module 143 may store the initial condition parameter into the storage unit 130.

The condition determining module 147 determines if the condition parameter difference is more than an abnormal condition threshold. If the condition parameter difference is more than the abnormal condition threshold, the LED of the LED lighting equipment is determined abnormal. Besides, the LED lighting equipment failure detecting system 100 may include a notice signal generating unit 160, such as a speaker, a light or any other element able to generate notice signals. The notice signal generating unit 160 is electrically connected with the control unit 140. If the LED 210 of the LED lighting equipment 200 is determined abnormal, the notice signal generating unit 160 generates a notice signal, such as a notice sound, a notice light or any other type of notice signal, to notice users that the LED 210 is abnormal. Therefore, if the LED 210 of the LED lighting equipment 200 is abnormal can be determined.

The condition parameter calculating module 143 may include a relation parameter calculator 144 and a condition parameter converter 145. The relation parameter calculator 144 calculates at least one relation parameter between the present current value and the present operating parameter. The condition parameter converter 145 converts the at least one relation parameter into the present condition parameter.

In one embodiment of this invention, if the measured present operating parameter is the present voltage of the LED 210, the relation parameter calculator 144 may calculate the at least one relation parameter utilizing the following formula:

$$log I = {\sum }_{i = 0}^{P} {α}_{i} {V}^{i}$$

Wherein, I is the present current value of the LED 210, V is the present voltage of the LED 210, P is a predefined natural number bigger than 1, and αᵢ is the at least one relation parameter to be calculated. Therefore, the at least one relation parameter αᵢ between the present current value I and the present voltage V can be calculated. Besides, if P is defined with a larger natural number, more relation parameter αᵢ can be calculated, such that the relation between the present current value I and the present voltage V can be quantized more precisely. Besides, to reduce computation quantity for the parameter calculator 144, the parameter calculator 144 can select at least one of several relation parameters to be the relation parameter αᵢ between the present current value I and the present voltage V. For example, the parameter calculator 144 may select the at least one relation parameter with minimal value of

$$log I - {\sum }_{i = 0}^{P} {α}_{i} {V}^{i}$$

to be the relation parameter αᵢ between the present current value I and the present voltage V. The condition parameter converter 145 converts the selected relation parameter into the present condition parameter utilizing a function. For example, if P is set to 1, α₀ and α₁ may be calculated by the parameter calculator 144. Therefore, the condition parameter converter 145 may convert the relation parameters α₀ and α₁ into the present condition parameter β utilizing the following function:

β=exp(−α₀/α₁)

Therefore, the condition parameter converter 145 may convert two relation parameters α₀ and α₁ into one present condition parameter β. In other embodiments, the condition parameter converter 145 may utilize a polynomial function or any other function to convert several relation parameters α₀ and α₁ into one present condition parameter, which should not be limited in this embodiment.

In another embodiment of this invention, if the measured present operating parameter is the present temperature of the LED 210, the relation parameter calculator 144 may calculate the at least one relation parameter utilizing the following formula:

$$T = {\sum }_{i = 0}^{P} {α}_{i} {I}^{i}$$

Wherein, I is the present current value of the LED 210, T is the present temperature of the LED 210, P is a predefined natural number bigger than 1, and αᵢ is the at least one relation parameter to be calculated. Therefore, the at least one relation parameter αᵢ between the present current value I and the present temperature T can be calculated. Besides, to reduce computation quantity for the parameter calculator 144, the parameter calculator 144 can select at least one of several relation parameters to be the relation parameter αᵢ between the present current value I and the present temperature T. For example, the parameter calculator 144 may select the at least one relation parameter with minimal value of

$$T - {\sum }_{i = 0}^{P} {α}_{i} {I}^{i}$$

to be the relation parameter αᵢ between the present current value I and the present temperature T. The condition parameter converter 145 converts the selected relation parameter into the present condition parameter utilizing a function.

In another embodiment of this invention, if the measured present operating parameter is the present intensity of the LED 210, the relation parameter calculator 144 may calculate the at least one relation parameter utilizing the following formula:

$$ξ = {\sum }_{i = 0}^{P} {α}_{i} {I}^{i}$$

Wherein, I is the present current value of the LED 210, ξ is the present luminance of the LED 210, P is a predefined natural number bigger than 1, and αᵢ is the at least one relation parameter to be calculated. Therefore, the at least one relation parameter αᵢ between the present current value I and the present luminance ξ can be calculated. Besides, to reduce computation quantity for the parameter calculator 144, the parameter calculator 144 can select at least one of several relation parameters to be the relation parameter αᵢ between the present current value I and the present luminance ξ. For example, the parameter calculator 144 may select the at least one relation parameter with minimal value of

$$ξ - {\sum }_{i = 0}^{P} {α}_{i} {I}^{i}$$

to be the relation parameter αᵢ between the present current value I and the present luminance ξ.

In another embodiment of this invention, if the measured present operating parameter is the present intensity of the LED 210, the relation parameter calculator 144 may calculate the at least one relation parameter utilizing the following formula:

$$I = {\sum }_{i = 0}^{P} {α}_{i} {C}^{i}$$

Wherein, I is the present current value of the LED 210, C is the present intensity of the LED 210, P is a predefined natural number bigger than 1, and αᵢ is the at least one relation parameter to be calculated. Therefore, the at least one relation parameter αᵢ between the present current value I and the present intensity C can be calculated. Besides, to reduce computation quantity for the parameter calculator 144, the parameter calculator 144 can select at least one of several relation parameters to be the relation parameter αᵢ between the present current value I and the present intensity C. For example, the parameter calculator 144 may select the at least one relation parameter with minimal value of

$$ξ - {\sum }_{i = 0}^{P} {α}_{i} {I}^{i}$$

to be the relation parameter αᵢ between the present current value I and the present intensity C.

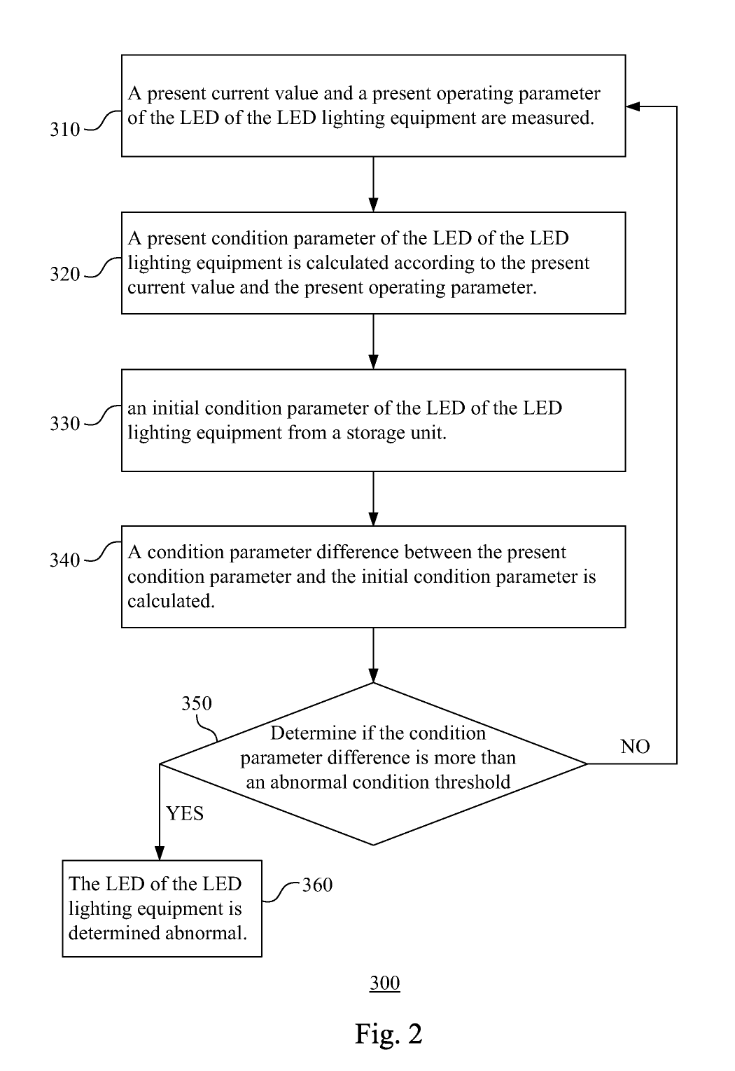

FIG. 2 is a flow diagram of an LED lighting equipment failure detecting method according to another embodiment of this invention. The LED lighting equipment failure detecting method is used for detecting if an LED lighting equipment is failure, wherein the LED lighting equipment includes at least one LED. In the LED lighting equipment failure detecting method, if the LED lighting equipment is failure is determined according to the relation between the present current value and the present operating parameter of the LED of the LED lighting equipment. The LED lighting equipment failure detecting method may take the form of a computer program product stored on a computer-readable storage medium having computer-readable instructions embodied in the medium. Any suitable storage medium may be used including non-volatile memory such as read only memory (ROM), programmable read only memory (PROM), erasable programmable read only memory (EPROM), and electrically erasable programmable read only memory (EEPROM) devices; volatile memory such as SRAM, DRAM, and DDR-RAM; optical storage devices such as CD-ROMs and DVD-ROMs; and magnetic storage devices such as hard disk drives and floppy disk drives.

The LED lighting equipment failure detecting method 300 includes the following steps:

In step 310, a present current value and a present operating parameter of the LED is measured. The present operating parameter of the LED of the LED lighting equipment may be temperature, intensity, voltage, luminance or any other types of the operating parameter of the LED of the LED lighting equipment.

In step 320, a present condition parameter of the LED of the LED lighting equipment is calculated according to the present current value and the present operating parameter. Wherein, during an initial stage, the present condition parameter may be stored into the storage unit as an initial condition parameter.

In step 330, an initial condition parameter of the LED of the LED lighting equipment is obtained from a storage unit.

In step 340, a condition parameter difference between the present condition parameter and the initial condition parameter is calculated. Wherein, subtraction, the method to calculate Pearson product-moment correlation coefficient, or any other method to calculate any other type of difference may be utilized to calculate the condition parameter difference in step 340.

In step 350, determine if the condition parameter difference is more than an abnormal condition threshold. If the condition parameter difference is not more than the abnormal condition threshold, a present current value and a present operating parameter of the LED are continually measured (step 310) to keep determining if the LED of the LED lighting equipment is abnormal.

If the condition parameter difference is more than the abnormal condition threshold, the LED of the LED lighting equipment is determined abnormal (step 360). Wherein, when the LED of the LED lighting equipment is determined abnormal (step 360), a notice signal, such as a notice sound, a notice light or any other type of notice signal, may be generated to notice users that the LED is abnormal.

Calculating a present condition parameter of the LED of the LED lighting equipment according to the present current value and the present operating parameter (step 320) may include the following steps: at least one relation parameter between the present current value and the present operating parameter may be calculated. Then, the at least one relation parameter may be converted into the present condition parameter.

In one embodiment of this invention, if the measured present operating parameter is the present voltage of the LED of the LED lighting equipment, the at least one relation parameter may be calculated utilizing the following formula:

$$log I = {\sum }_{i = 0}^{P} {α}_{i} {V}^{i}$$

Wherein, I is the present current value of the LED of the LED lighting equipment, V is the present voltage of the LED of the LED lighting equipment, P is a predefined natural number bigger than 1, and αᵢ is the at least one relation parameter to be calculated. Therefore, the at least one relation parameter αᵢ between the present current value I and the present voltage V can be calculated. Besides, if P is defined with a larger natural number, more relation parameter αᵢ can be calculated, such that the relation between the present current value I and the present voltage V can be quantized more precisely. Besides, to reduce computation quantity, at least one of several relation parameters can be selected to be the relation parameter αᵢ between the present current value I and the present voltage V. For example, the at least one relation parameter with minimal value of

$$log I - {\sum }_{i = 0}^{P} {α}_{i} {V}^{i}$$

may be selected to be the relation parameter αᵢ between the present current value I and the present voltage V. The selected relation parameter may be converted into the present condition parameter utilizing a function. For example, if P is set to 1, α₀ and α₁ may be calculated. Therefore, the relation parameters α₀ and α₁ may be converted into the present condition parameter β utilizing the following function:

β=exp(−α₀/α₁)

Therefore, two relation parameters α₀ and α₁ may be converted into one present condition parameter β. In other embodiments, a polynomial function or any other function may be utilized to convert several relation parameters α₀ and α₁ into one present condition parameter, which should not be limited in this embodiment.

In another embodiment of this invention, if the measured present operating parameter is the present temperature of the LED of the LED lighting equipment, the at least one relation parameter may be calculated utilizing the following formula:

$$T = {\sum }_{i = 0}^{P} {α}_{i} {I}^{i}$$

Wherein, I is the present current value of the LED of the LED lighting equipment, T is the present temperature of the LED of the LED lighting equipment, P is a predefined natural number bigger than 1, and αᵢ is the at least one relation parameter to be calculated. Therefore, the at least one relation parameter αᵢ between the present current value I and the present temperature T can be calculated. Besides, to reduce computation quantity, at least one of several relation parameters can be selected to be the relation parameter αᵢ between the present current value I and the present temperature T. For example, the at least one relation parameter with minimal value of

$$T - {\sum }_{i = 0}^{P} {α}_{i} {I}^{i}$$

may be selected to be the relation parameter αᵢ between the present current value I and the present temperature T. The selected relation parameter is converted into the present condition parameter utilizing a function.

In another embodiment of this invention, if the measured present operating parameter is the present intensity of the LED of the LED lighting equipment, the at least one relation parameter may be calculated utilizing the following formula:

$$ξ = {\sum }_{i = 0}^{P} {α}_{i} {I}^{i}$$

Wherein, I is the present current value of the LED of the LED lighting equipment, is the present luminance of the LED of the LED lighting equipment, ξ is a predefined natural number bigger than 1, and αᵢ is the at least one relation parameter to be calculated. Therefore, the at least one relation parameter αᵢ between the present current value I and the present luminance ξ can be calculated. Besides, to reduce computation quantity, at least one of several relation parameters can be selected to be the relation parameter αᵢ between the present current value I and the present luminance ξ. For example, the at least one relation parameter with minimal value of

$$ξ - {\sum }_{i = 0}^{P} {α}_{i} {I}^{i}$$

may be selected to be the relation parameter αᵢ between the present current value I and the present luminance ξ.

In another embodiment of this invention, if the measured present operating parameter is the present intensity of the LED of the LED lighting equipment, the at least one relation parameter may be calculated utilizing the following formula:

$$I = {\sum }_{i = 0}^{P} {α}_{i} {C}^{i}$$

Wherein, I is the present current value of the LED of the LED lighting equipment, C is the present intensity of the LED of the LED lighting equipment, P is a predefined natural number bigger than 1, and αᵢ is the at least one relation parameter to be calculated. Therefore, the at least one relation parameter αᵢ between the present current value I and the present intensity C can be calculated. Besides, to reduce computation quantity, at least one of several relation parameters can be selected to be the relation parameter αᵢ between the present current value I and the present intensity C. For example, the at least one relation parameter with minimal value of

$$ξ - {\sum }_{i = 0}^{P} {α}_{i} {I}^{i}$$

may be selected to be the relation parameter αᵢ between the present current value I and the present intensity C.

Above all, if the LED of the LED lighting equipment is abnormal can be determined according to the current value and operating parameter of the LED of the LED lighting equipment. In addition, if an initial stage is set, the initial condition parameter can be obtained for latter abnormality determination. Therefore, even if different LEDs or LED lighting equipments are applied, abnormality thereof can be determined after setting to the initial stage. Besides, different types of abnormality, such as overheat, open circuit, short circuit, decreased LED emitting capability, abnormal intensity control or any other abnormality, can be determined. In addition, several LED lighting equipments can share a single control, which save cost.

Although the present invention has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An LED lighting equipment failure detecting system for detecting if an LED lighting equipment is failure, wherein the LED lighting equipment comprises at least one LED, the LED lighting equipment failure detecting system comprises:
a current measuring unit, measuring a present current value of the LED;
a parameter measuring unit, measuring a present operating parameter of the LED;
a storage unit, wherein an initial condition parameter of the LED is stored in the storage unit; and
a control unit, building connections with the current measuring unit and the parameter measuring unit, and electrically connected with the storage unit, the control unit comprises:
a receiving module, receiving the present current value from the current measuring unit, and receiving the present operating parameter from the parameter measuring unit;
a condition parameter calculating module, calculating a present condition parameter of the LED of the LED lighting equipment according to the present current value and the present operating parameter;
a difference calculating module, calculating a condition parameter difference between the present condition parameter and the initial condition parameter; and
a condition determining module, determining if the condition parameter difference is more than an abnormal condition threshold, wherein if the condition parameter difference is more than the abnormal condition threshold, the LED of the LED lighting equipment is determined abnormal.

2. The LED lighting equipment failure detecting system of claim 1, wherein the condition parameter calculating module comprises:
a relation parameter calculator, calculating at least one relation parameter between the present current value and the present operating parameter; and
a condition parameter converter, converting the at least one relation parameter into the present condition parameter.

3. The LED lighting equipment failure detecting system of claim 1, wherein the control unit builds connections with the current measuring unit and the parameter measuring unit through electrical connection.

4. The LED lighting equipment failure detecting system of claim 1, further comprising:
a data transmission interface, wherein the control unit builds connections with the current measuring unit and the parameter measuring unit through the data transmission interface.

5. The LED lighting equipment failure detecting system of claim 1, further comprising:
a notice signal generating unit, electrically connected with the control unit, wherein if the LED of the LED lighting equipment is determined abnormal, the notice signal generating unit generates a notice signal.

6. The LED lighting equipment failure detecting system of claim 1 wherein when the LED lighting equipment failure detecting system is set to an initial stage, the condition parameter calculating module takes the present condition parameter as the initial condition parameter, and the condition parameter calculating module stores the initial condition parameter into the storage unit.

7. The LED lighting equipment failure detecting system of claim 1, wherein the parameter measuring unit is a temperature measuring unit, an intensity measuring unit, a voltage measuring unit or a luminance measuring unit.

8. An LED lighting equipment failure detecting method for detecting if an LED lighting equipment is failure, wherein the LED lighting equipment comprises at least one LED, the LED lighting equipment failure detecting method comprises:
measuring a present current value and a present operating parameter of the LED;
calculating a present condition parameter of the LED of the LED lighting equipment according to the present current value and the present operating parameter;
obtaining an initial condition parameter of the LED of the LED lighting equipment from a storage unit;
calculating a condition parameter difference between the present condition parameter and the initial condition parameter;
determining if the condition parameter difference is more than an abnormal condition threshold; and
if the condition parameter difference is more than the abnormal condition threshold, determining that the LED of the LED lighting equipment is abnormal.

9. The LED lighting equipment failure detecting method of claim 8, wherein calculating the present condition parameter of the LED of the LED lighting equipment according to the present current value and the present operating parameter comprises:
calculating at least one relation parameter between the present current value and the present operating parameter; and
converting the at least one relation parameter into the present condition parameter.

10. The LED lighting equipment failure detecting method of claim 8, further comprising:
if the LED of the LED lighting equipment is determined abnormal, generating a notice signal.

11. The LED lighting equipment failure detecting method of claim 8, further comprising:
storing the present condition parameter into the storage unit as the initial condition parameter during an initial stage.

12. The LED lighting equipment failure detecting method of claim 8, wherein the present operating parameter of the LED of the LED lighting equipment is temperature, intensity, voltage or luminance of the LED of the LED lighting equipment.

13. A computer-readable storage medium with a computer program to execute an LED lighting equipment failure detecting method for detecting if an LED lighting equipment is failure, wherein the LED lighting equipment comprises at least one LED, the LED lighting equipment failure detecting method comprises:
measuring a present current value and a present operating parameter of the LED;
calculating a present condition parameter of the LED of the LED lighting equipment according to the present current value and the present operating parameter;
obtaining an initial condition parameter of the LED of the LED lighting equipment from a storage unit;
calculating a condition parameter difference between the present condition parameter and the initial condition parameter;
determining if the condition parameter difference is more than an abnormal condition threshold; and
if the condition parameter difference is more than the abnormal condition threshold, determining that the LED of the LED lighting equipment is abnormal.

14. The computer-readable storage medium of claim 13, wherein calculating the present condition parameter of the LED of the LED lighting equipment according to the present current value and the present operating parameter comprises:
calculating at least one relation parameter between the present current value and the present operating parameter; and
converting the at least one relation parameter into the present condition parameter.

15. The computer-readable storage medium of claim 13, wherein the LED lighting equipment failure detecting method further comprises:
if the LED of the LED lighting equipment is determined abnormal, generating a notice signal.

16. The computer-readable storage medium of claim 13, wherein the LED lighting equipment failure detecting method further comprises:
storing the present condition parameter into the storage unit as the initial condition parameter during an initial stage.

17. The computer-readable storage medium of claim 13, wherein the present operating parameter of the LED of the LED lighting equipment is temperature, intensity, voltage or luminance of the LED of the LED lighting equipment.
